(19) United States
(12) Patent Application Publication
(10) Pub. No.: US 2008/0006827 A1
(43) Pub. Date: Jan. 10, 2008

(54) Making thin film transistors on display panels

(75) Inventors: Seung-Hwan Shim, Seongnam-si (KR); Kwan-Wook Jung, Suwon-si (KR); Young-Jin Chang, Yongin-si (KR); Jae-Beom Choi, Suwon-si (KR); Yoon-Seok Choi, Suwon-si (KR)

Correspondence Address: MACPHERSON KWOK CHEN & HEID LLP, 2033 GATEWAY PLACE, SUITE 400, SAN JOSE, CA, 95110, US

(73) Assignee: Samsung Electronics Co., Ltd.

(21) Appl. No.: 11/788,501

(22) Filed: Apr. 20, 2007

(30) Foreign Application Priority Data
Jul. 6, 2006 (KR) 10-2006-0063588

(51) Int. Cl. H01L 31/036; H01L 21/84

(52) U.S. Cl. 257/72; 438/166; 257/E31.04; 257/E21.703

(57) ABSTRACT

A thin film transistor for a display device includes a substrate, a gate electrode formed on the substrate, a gate insulating layer formed on the gate electrode, a polycrystalline semiconductor formed on the gate insulating layer and overlapping the gate electrode, a source electrode partially overlapping the polycrystalline semiconductor, and a drain electrode partially overlapping the polycrystalline semiconductor. The polycrystalline semiconductor includes a plurality of first polycrystalline semiconductors that are doped with conductive impurities and a plurality of second polycrystalline semiconductors that are not doped with conductive impurities, and the first polycrystalline semiconductors are disposed between and connected in series with adjacent ones of the second polycrystalline semiconductors.

### RELATED APPLICATIONS

This application claims priority of Korean Patent Application No. 10-2006-0063588, filed Jul. 6, 2006, the entire disclosure of which is incorporated herein by reference.

### BACKGROUND

This disclosure relates to thin film transistors (TFTs) for panels of display devices and to methods for making them.

In general, flat panel displays, such as liquid crystal displays (LCDs), organic light emitting diode (OLED) displays, and electrophoretic displays, include a plurality of pairs of electric field generating electrodes with an electro-optically active layer interposed therebetween. One of each pair of the electric field generating electrodes is conventionally connected to a switching device through which electric signals are applied to it. The electro-optically active layer converts the electric signals into optical signals to display an image.

An LCD includes a layer of liquid crystal material as the electro-optically active layer, and an OLED includes a layer of an organic light emitting material as the electro-optically active layer.

Flat panel displays use thin film transistors (TFTs), which are three-terminal devices, as the switching device, and include gate lines that transmit scan signals for controlling the TFT, and data lines that transmit signals that are applied to a pixel electrode.

The TFTs include a thin film made of an amorphous semiconductor or a polycrystalline semiconductor. Since the amorphous semiconductor can be formed at low temperatures, the amorphous semiconductor is widely used for display devices in which a glass or a plastic having a low melting point is used as a substrate of the display. One of the advantages of the amorphous semiconductor thin film is that it has a lower leakage current when compared with a polycrystalline semiconductor. However, the amorphous semiconductor thin film also has a relatively low field effect mobility, which militates against its use at higher operational speeds.

By contrast, the polycrystalline semiconductor thin film has a relatively high field effect mobility. However, since the polycrystalline semiconductor thin film requires crystallizing the semiconductor on the substrate, it generally also requires that a top gate structure be employed, which results in TFTs having a more complicated structure and that entail more complicated manufacturing processes, thereby substantially increasing manufacturing costs.

Recently, polycrystalline silicon TFTs employing a bottom gate structure using a solid phase crystallization process have been proposed. However, in these structures, a strong vertical electric field is formed at a portion at which the drain electrode and the semiconductor of the structure overlap, so that electrons are accelerated by the vertical electric field so as to collide with and ionize atoms, thereby generating holes. The holes then move to the source electrode of the structure though a back channel, causing the potential barrier of the source junction region to be lowered. As a result, a “kink” effect occurs, in which a large amount of charges is injected from the source electrode. This kink effect causes several problems, such as an increase in leakage current, an increase in power consumption, and undesirable crosstalk.

### BRIEF SUMMARY

In accordance with the exemplary embodiments thereof described herein, the present invention provides TFTs having an increased field effect mobility and a reduced leakage current, and methods for manufacturing them using simplified manufacturing processes.

In one exemplary embodiment, a TFT includes a substrate, a gate electrode formed on the substrate, a gate insulating layer formed on the gate electrode, a polycrystalline semiconductor formed on the gate insulating layer and overlapping the gate electrode, a source electrode partially overlapping the polycrystalline semiconductor, and a drain electrode partially overlapping the polycrystalline semiconductor. The polycrystalline semiconductor comprises at least one first polycrystalline semiconductor that is doped with impurities and at least two second polycrystalline semiconductors that are not doped with impurities, and the first polycrystalline semiconductor is disposed between ones of the second semiconductors.

The TFT may further include ohmic contacts respectively disposed between the source electrode, and the second polycrystalline semiconductor, and between the drain electrode, and the second polycrystalline semiconductor. The ohmic contacts may incorporate substantially the same patterns as those of the source and drain electrodes, and both the ohmic contacts and the first polycrystalline semiconductor may be made of the same material. The source and drain electrodes may overlap the second polycrystalline semiconductor. The impurities are n-type.

In another exemplary embodiment, a display panel includes a first substrate, a gate line formed on the first substrate, a data line connected to the above TFT and intersecting the gate line, and a pixel electrode connected to the TFT.

In another exemplary embodiment, a method is provided for manufacturing a TFT, the method including; forming a gate electrode on a substrate; forming a first amorphous silicon layer on the gate electrode; forming a silicon pattern by patterning the first amorphous silicon layer; forming a second amorphous silicon layer that is doped with impurities on the silicon pattern; forming a first polycrystalline semiconductor and a polycrystalline silicon layer by crystallizing the silicon pattern and the second amorphous silicon layer; forming a metal layer on the polycrystalline silicon layer; and forming a metal pattern, a second polycrystalline semiconductor, and ohmic contacts by patterning the metal layer and the polycrystalline silicon layer.

In another exemplary embodiment, a method for manufacturing a display panel includes: forming a gate line on a substrate; forming a first amorphous silicon layer on the gate line; forming a silicon pattern by patterning the first amorphous silicon layer; forming a second amorphous silicon layer that is doped with impurities on the silicon pattern; forming a first polycrystalline semiconductor and a polycrystalline silicon layer by crystallizing the silicon pattern and the second amorphous silicon layer; forming a metal layer on the polycrystalline silicon layer; forming a data line, a drain electrode, a metal pattern, a second polycrystalline semiconductor, and ohmic contacts by patterning the metal layer and the polycrystalline silicon layer; forming a passivation layer, including contact holes that expose the drain electrode on the data line, the drain electrode, the first polycrystalline semiconductor and the second polycrystalline semiconductor; and forming a pixel electrode connected to the drain electrode through the contact holes on the passivation layer.

The silicon pattern and the second amorphous silicon layer is crystallized by a solid phase crystallization (SPC) process.

The formation of the metal pattern, the second polycrystalline semiconductor, and the ohmic contacts further comprises: forming first and second photoresist layers on the metal layer, the second layer being thicker than the first layer; forming the metal pattern, the second polycrystalline semiconductor, and ohmic contacts by patterning the metal layer and the polycrystalline silicon layer using the first and second photoresist layers as masks;

removing the first photoresist layer on the metal pattern; etching to remove the metal pattern using the second photoresist layer as a mask; and, removing the second photoresist layer.

A better understanding of the above and many other features and advantages of the novel TFTs, panels incorporating them, and the methods for making them of the present invention may be obtained from a consideration of the detailed description of some exemplary embodiments thereof below, particularly if such consideration is made in conjunction with the appended drawings, wherein like reference numerals are used to identify like elements illustrated in one or more of the figures thereof.

### BRIEF DESCRIPTION OF THE DRAWINGS

FIG. 1 is a partial plan view of an exemplary embodiment of a liquid crystal display (LCD) in accordance with the present invention, showing a single pixel area thereof;

FIG. 2 is a partial plan view of an exemplary embodiment of a TFT (TFT) panel of the exemplary LCD of FIG. 1;

FIG. 3 is a partial plan view of an exemplary embodiment of a common electrode panel of the exemplary LCD of FIG. 1;

FIGS. 4 and 5 are partial cross sectional views of the LCD of FIG. 1, as respectively seen along the section lines IV-IV and V-V taken therein;

FIG. 6 is a partial plan view of an exemplary TFT panel, showing an intermediate process of an exemplary embodiment of a method for manufacturing the panel in accordance with the present invention;

FIGS. 7 and 8 are partial cross sectional views of the exemplary TFT panel of FIG. 6, as respectively seen along the section lines VII-VII and VIII-VIII taken therein;

FIG. 9 is a partial plan view of the exemplary TFT panel of FIG. 6, showing a next succeeding process in the exemplary manufacturing method therefor;

FIGS. 10 and 11 are partial cross sectional views of the TFT panel of FIG. 9, as respectively seen along the section lines X-X and XI-XI taken therein;

FIG. 12 is a partial plan view of the TFT panel of FIG. 9, showing a next succeeding process in the exemplary manufacturing method therefor;

FIGS. 13 and 14 are partial cross sectional views of the TFT panel of FIG. 9, as respectively seen along the section lines XIII-XIII and XIV-XIV taken therein;

FIGS. 15 and 16 are partial cross sectional views of the TFT panel of FIGS. 13 and 14, respectively showing next succeeding processes of the exemplary manufacturing method therefor;

FIG. 17 is a partial plan view of the TFT panel of FIGS. 15 and 16, showing a next succeeding process of the exemplary manufacturing method therefor;

FIGS. 18 and 19 are partial cross sectional views of the TFT panel of FIG. 17, as respectively seen along the section lines XVIII-XVIII and XIX-XIX taken therein;

FIG. 20 is a partial plan view of the TFT panel of FIG. 17, showing a next succeeding step of the exemplary manufacturing method therefor;

FIGS. 21 and 22 are partial cross sectional views of the TFT panel of FIG. 20, as respectively seen along the section lines XXI-XXI and XXII-XXII taken therein;

FIG. 23 is a partial plan view of the TFT panel of FIG. 20, showing a next succeeding process of the exemplary manufacturing method therefor;

FIGS. 24 and 25 are partial cross sectional views of the TFT panel of FIG. 20, as respectively seen along the section lines XXIV-XXIV and XXV-XXV taken therein;

FIG. 26 is a partial equivalent circuit diagram of an exemplary embodiment of an organic light emitting diode (OLED) display in accord with the present invention;

FIG. 27 is a partial plan view of the exemplary OLED display of FIG. 26, showing a single pixel area thereof; and,

FIGS. 28 and 29 are partial cross sectional views of the exemplary OLED display of FIG. 27, as respectively seen along the section lines XXVIII-XXVIII and XXIX-XXIX taken therein.

### DETAILED DESCRIPTION

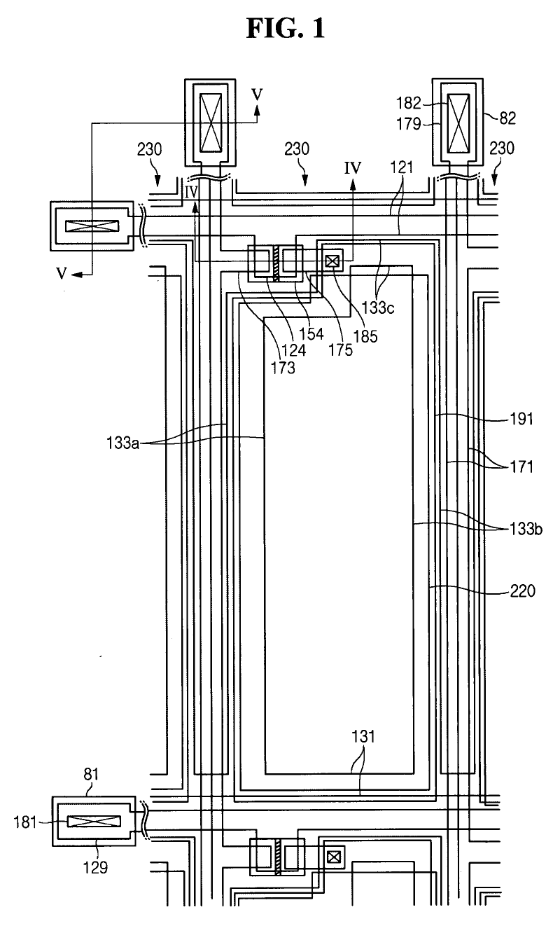

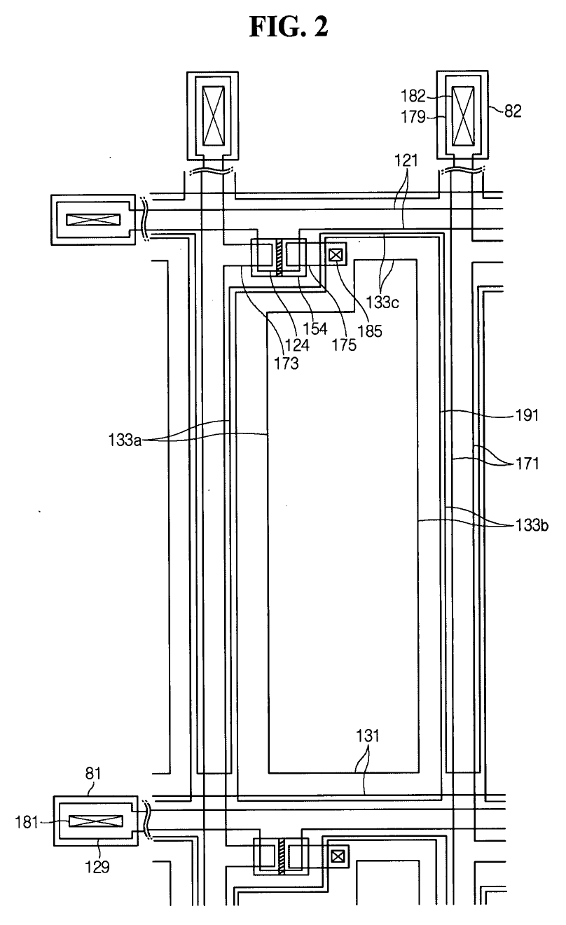

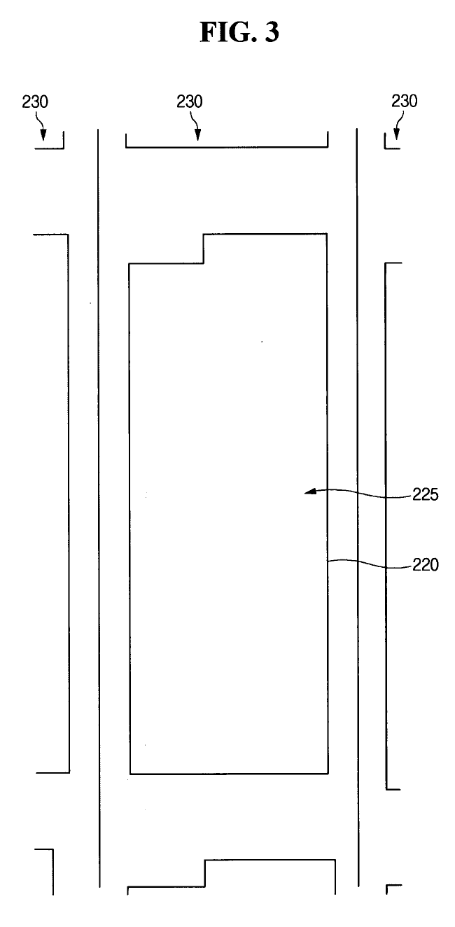

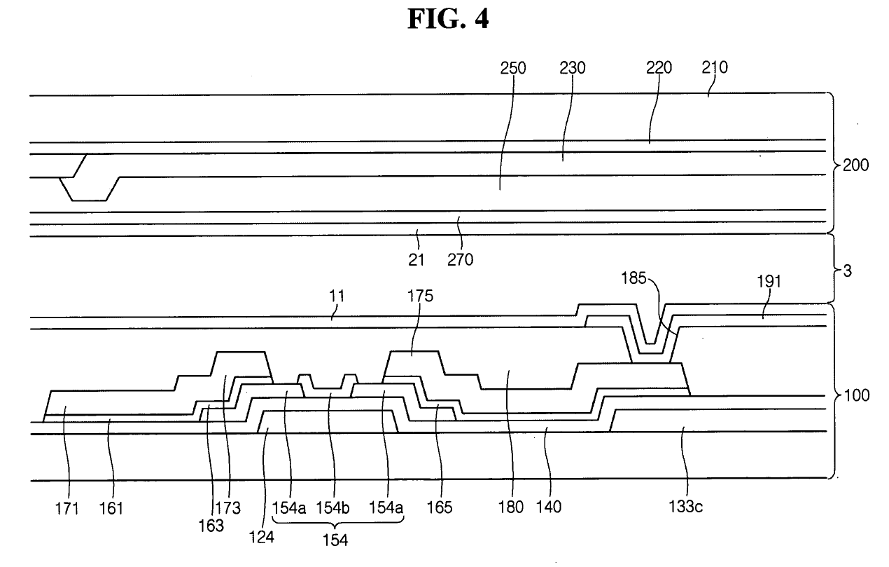

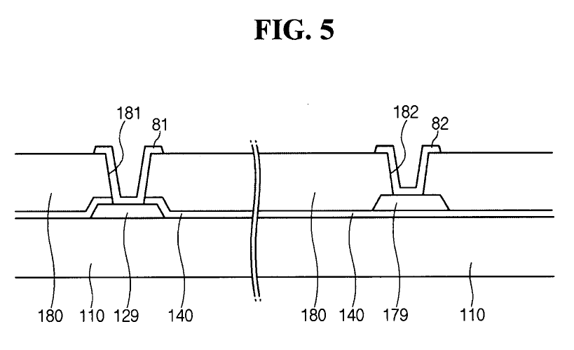

An exemplary embodiment of a thin film transistor (TFT) panel in accordance with the present invention is described below in detail with reference to FIGS. 1 to 5, wherein FIG. 1 is a partial plan view of the exemplary LCD, showing a single pixel area thereof, FIG. 2 is a partial plan view of an exemplary embodiment of a TFT panel of the exemplary LCD of FIG. 1, FIG. 3 is a partial plan view of an exemplary embodiment of a common electrode panel of the exemplary LCD of FIG. 1, and FIGS. 4 and 5 are partial cross sectional views of the exemplary LCD of FIG. 1, as respectively seen along the section lines IV-IV and V-V taken therein.

Referring to FIGS. 1 to 5, the exemplary LCD includes a TFT panel 100 and a common electrode panel 200 disposed in facing opposition to each other, and a layer 3 of a liquid crystal material interposed between the two panels 100 and 200.

The TFT panel 100 is described first with reference to FIGS. 1, 2, 4, and 5. A plurality of gate lines 121 and a plurality of storage electrode lines 131 are formed on an insulating substrate 110 made of a transparent glass or a plastic material. The gate lines 121 transmit gate signals, and in the figures hereof, extend in a generally horizontal direction. Each of the gate lines 121 includes a plurality of gate electrodes 124 extending downwardly and an end portion 129 having a wide area for connection to other layers or to an external driving circuit. A gate driving circuit (not illustrated) for generating the gate signals may be mounted on a flexible printed circuit film (not illustrated) that is mounted on the substrate 110. Alternatively, the gate driving circuit may be mounted directly on the substrate 110 or otherwise integrated on the substrate 110. In an embodiment in which the gate driving circuit is integrated on the substrate 110, the gate lines 121 may be extended to connect directly to the gate driving circuit.

The storage electrode lines 131 have a selected voltage applied to them and extend generally parallel to the gate lines 121. Additionally, the storage electrode lines include a plurality of vertically extending storage electrodes 133a and 133b that diverge from the storage electrode lines 131, and a transverse storage electrode 133c. As illustrated in, e.g., FIG. 1, each of the storage electrode lines 131 is disposed between a pair of adjacent gate lines 121 and is disposed closer to the lower one of the two gate lines 121. The longitudinal storage electrodes 133a and 133b are connected to the storage electrode line 131 and extend toward an adjacent gate line 121. The transverse storage electrode 133c is connected between opposite sides of the longitudinal storage electrodes 133a and 133b, which are not connected to the storage electrode line 131. The transverse storage electrode 133c may have a downwardly angled portion. Of course, the shapes of the storage electrode lines 131 and the storage electrodes 133a, 133b, and 133c can be modified in a variety of ways, and need not necessarily conform to those of the particular exemplary embodiment illustrated in the figures.

The gate lines 121 and the storage electrode lines 131 may be made of an aluminum-based metal, such as pure aluminum (Al) or an aluminum alloy, a silver-based metal, such as pure silver (Ag) or a silver alloy, a copper-based metal, such as pure copper (Cu) or a copper alloy, a molybdenum-based metal, such as pure molybdenum (Mo) or a molybdenum alloy, chromium (Cr), tantalum (Ta) or titanium (Ti) or the like. Further, the gate lines 121 and the storage electrode lines 131 may incorporate a multi-layered structure that includes, e.g., two conductive layers (not illustrated) having different physical properties. For example, one of the two conductive layers may be made of a metal having a low resistivity, such as an aluminum-based metal, a silver-based metal, or a copper-based metal, in order to reduce signal delay or voltage drop. The other conductive layer may then preferably be made of a material having good physical, chemical, and/or electrical contact properties with other materials, and in particular, with indium tin oxide (ITO) or indium zinc oxide (IZO), such as a molybdenum-, chromium-, titanium-, or tantalum-based metals. A combination of a lower chromium-containing layer and an upper aluminum-containing layer, and a combination of a lower aluminum containing layer and an upper molybdenum containing layer, are good examples of such multi-layered construction. However, the gate lines 121 and the storage electrode lines 131 may also be made of many various other types of metals and conductive materials.

In one preferred embodiment, the side surfaces of the gate lines 121 and storage electrode lines 131 are made slanted with respect to the surface of the insulating substrate 110 on which they are disposed, and the angle of the slant is desirably within a range of from about 30° to about 80°.

A gate insulating layer 140, made of, e.g., a silicon nitride (SiNx), a silicon oxide (SiOx), or the like, is formed over the gate lines 121 and the storage electrode lines 131, as illustrated in the cross-sectional views of FIGS. 4 and 5. A plurality of island-shaped semiconductors 154 made of a polycrystalline silicon are then formed at selected locations on the gate insulating layer 140, as illustrated in FIGS. 1 and 2. In particular, the semiconductors 154 are disposed on the gate electrodes 124.

The island-shaped semiconductors 154 include first polycrystalline semiconductors 154a, which are not doped with impurities, and second polycrystalline semiconductors 154b, which are doped with impurities. The second polycrystalline semiconductors 154b are made of a polycrystalline silicon that is heavily doped with n-type impurities, such as phosphorus (P) or the like.

As illustrated in FIG. 4, a plurality of line-shaped and island-shaped ohmic contacts 161 and 165 are then formed on the island-shaped semiconductors 154. The ohmic contacts 161 and 165 are made of the same material as the second polycrystalline semiconductors 154b. The line-shaped ohmic contacts 161 extend in a generally horizontal direction in the figures and include a plurality of protrusions 163 that protrude toward the gate lines 124. A pair of the protrusion 163 and the island-shaped ohmic contact 165 are disposed on the first polycrystalline semiconductors 154a.

In one preferred embodiment, the side surfaces of the semiconductors 154 and the ohmic contacts 161 and 165 are slanted with respect to the surface of the insulating substrate 110, and desirably, the angle of the slant is in a range of from about 30° to about 80°.

As illustrated in FIGS. 1 and 2, a plurality of data lines 171 and a plurality of drain electrodes 175 are then formed on the ohmic contacts 161 and 165. Each of the data lines 171 transmits a respective data signal and extends in a generally vertical direction in the figures so as to intersect the gate lines 121 orthogonally. Each of the data lines 171 also intersects the storage electrode lines 131 and runs between a pair of adjacent storage electrodes 133a and 133b. Each of the data lines 171 includes a plurality of source electrodes 173 that extend toward the gate electrodes 124 and an end portion 179 having a wide area for connection to other layers or an external data driving circuit (not illustrated). The data driving circuit that generates the respective data signals may be mounted either on a flexible printed circuit film (not illustrated) attached on the substrate 110, or alternatively, may be directly mounted on the substrate, or may be otherwise integrated on the substrate 110. In an embodiment in which the data driving circuit is integrated on the substrate 110, the data lines 171 may be extended to directly connect to the data driving circuit.

The drain electrode 175 is separated from and faces toward the data line 171, with the gate electrode 124 interposed therebetween. One gate electrode 124, one source electrode 173, and one drain electrode 175, together with an associated one of the island-shaped semiconductors 154, constitute one TFT. The channel of the TFT is formed in the island-shaped semiconductors 154 between the source electrode 173 and the drain electrode 175.

In one exemplary embodiment, the semiconductor 154 comprises the first and second polycrystalline semiconductors 154a and 154b, so that holes on the side of the drain electrode 175 are partially blocked by the second polycrystalline semiconductor 154b. This arrangement enables the “kink” effect described above to be controlled, and results in a decrease in the leakage current of the device.

The data lines 171 and the drain electrodes 175 are preferably made of a refractory metal, such as molybdenum (Mo), chromium (Cr), tantalum (Ta), or titanium (Ti), or of respective alloys thereof. The data lines 171 and the drain electrodes 175 may incorporate a multi-layered structure, including, e.g., a refractory metal layer and a low-resistivity conductive layer (not illustrated). Other examples of multi-layered structures comprise a two-layered structure of a lower chromium- or molybdenum-containing layer and an upper aluminum-containing layer, and a three-layered structure comprising a lower molybdenum-containing layer, an intermediate aluminum-containing layer, and an upper molybdenum-containing layer. However, it should be understood that the data lines 171 and drain electrodes 175 can be made of many other various types of metals or conductive materials than those described above.

In one preferred embodiment, the side surfaces of the data lines 171 and the drain electrodes 175 are also slanted with respect to the surface of the insulating substrate 110, desirably with a slant angle in the range of from about 30° to about 80°.

The ohmic contacts 161 and 165, the data lines 171, and the drain electrodes 175 preferably all have substantially the same planar pattern. The ohmic contacts 163 and 165 are interposed between the drain electrodes 175, the source electrodes 173, and the semiconductors 154, and function to reduce the respective contact resistances therebetween.

As illustrated in the cross-sectional views of FIGS. 4 and 5, a passivation layer 180 is formed on the data lines 171, the drain electrodes 175, and the exposed portions of the semiconductor 154. The passivation layer 180 may be made of an organic or an inorganic insulating material, and its upper surface may be planarized. Examples of inorganic insulating materials that may be used include SiNx and SiOx, and the organic insulating materials that may be used may have photosensitivity, and preferably, a dielectric constant of 4.0 or less. Alternatively, the passivation layer 180 may comprise a two-layered structure of a lower inorganic layer and an upper organic layer in order to provide the excellent insulating property of an organic layer and to protect the exposed protrusions 154.

A plurality of contact holes 182 and 185 that expose the end portions 179 of the data lines 171 and the drain electrodes 175, respectively, are formed in the passivation layer 180. A plurality of contact holes 181 that expose the end portions 129 of the gate lines 121 are also formed in the passivation layer 180 and the gate insulating layer 140.

A plurality of pixel electrodes 191 and a plurality of contact assistants 81 and 82 are formed on the passivation layer 180. These components may be made of a transparent conductive material, such as indium tin oxide (ITO) and indium zinc oxide (IZO), or the like, or of a reflective metal, such as aluminum (Al), silver (Ag), chromium (Cr), or respective alloys thereof.

The pixel electrode 191 is physically and electrically connected to the drain electrode 175 through the contact hole 185 and receives a data voltage that is applied by the drain electrode 175. The pixel electrode 191 to which the data voltage is applied, together with a common electrode of another panel (not illustrated) to which a common voltage is applied, generate an electric filed. The electric filed determines the alignment of the molecules of the liquid crystal layer disposed between the two electrodes. The particular alignment of the liquid crystal molecules determines the polarization of the light passing through the liquid crystal layer 3. The pixel electrode 191 and the common electrode (not illustrated) further constitute a capacitor (hereinafter, referred to as a liquid crystal capacitor) that acts to sustain the voltage that was previously applied between the two electrodes after the TFT is turned off.

The pixel electrodes 191 overlap the storage electrode lines 131, including the storage electrodes 133a, 133b, and 133c. The capacitors that are formed by overlapping the pixel electrodes 191 and the drain electrodes 175 electrically connected thereto with the storage electrodes 133c are called storage capacitors. The storage capacitors enhance the voltage sustaining capacity of the liquid crystal capacitors described above.

The contact assistants 81 and 82 are connected to the end portion 129 of the gate line 121 and the end portion 179 of the data line 171 through the contact holes 181 and 182, respectively. The contact assistants 81 and 82 function to compensate for differences in the adhesiveness of the end portions 129 of the gate lines 121 and the end portions 179 of the data lines 171 and those of external apparatuses to which they are connected and also to protect these portions.

The common electrode panel of the exemplary LCD is now described with reference to FIGS. 1 and 3 to 5. As illustrated in FIG. 1, a light blocking member 220 is formed on an insulating substrate 210 made of a transparent glass or plastic material. The light blocking member 220 is called a black matrix and functions to prevent light leakage between the pixel electrodes 191. The light blocking member 220 includes a plurality of opening portions 225 which face the pixel electrodes 191 and have shapes similar to those of the pixel electrodes 191. However, the light blocking member 220 may also be constructed with portions that correspond to the gate lines 121, the data lines 171 and the TFT.

A plurality of color filters 230 are formed on the substrate 210. Most portions of the color filters 230 are disposed in regions surrounded by the light blocking member 220, and the color filters 230 may extend along rows of the pixel electrodes 191, i.e., in the horizontal direction in the figures. Each of the color filters 230 displays one of a set of primary colors, such as red, green, and blue.

In the particular exemplary embodiment of FIG. 4, an overcoat 250 is formed on the color filters 230 and the light blocking member 220. The overcoat 250 may comprise an organic insulating material. The overcoat 250 prevents the color filters 230 from being exposed and provides a planarized surface. However, in an alternative embodiment, the overcoat 250 can be omitted.

As illustrated in FIG. 4, a common electrode 270 is formed on the overcoat 250. The common electrode 270 may be made of a transparent conductive material, such as ITO or IZO.

Alignment layers 11 and 21 are coated on inner surfaces of the panels 100 and 200. Polarizers (not illustrated) are disposed on respective outer surfaces of the panels 100 and 200. In a reflective type of LCD, one of the two polarizers may be omitted.

The exemplary LCD may further include a phase retardation film (not illustrated) for compensating for retardation of the liquid crystal layer 3. The LCD may also include a backlight unit (not illustrated) for supplying light to the polarizers, the phase retardation film, the panels 100 and 200, and the liquid crystal layer 3.

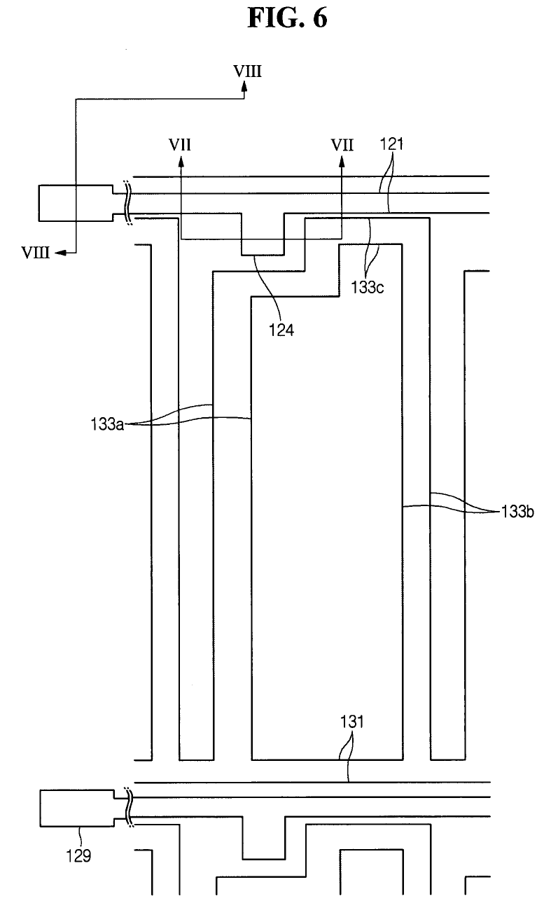

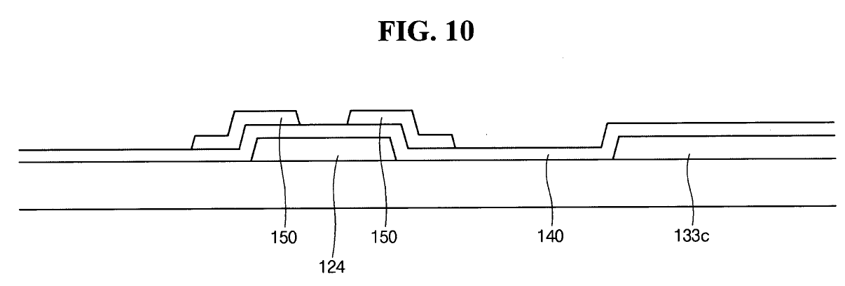

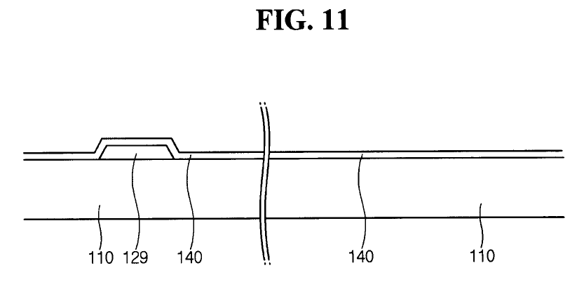

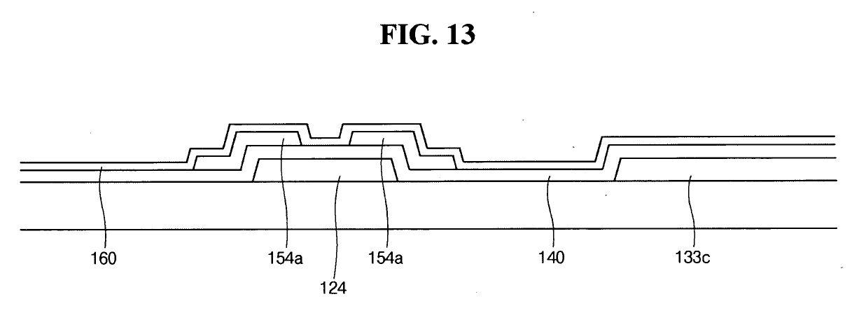

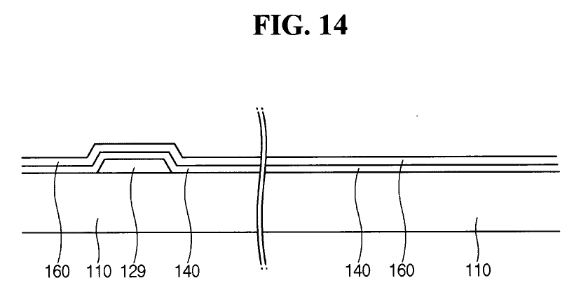

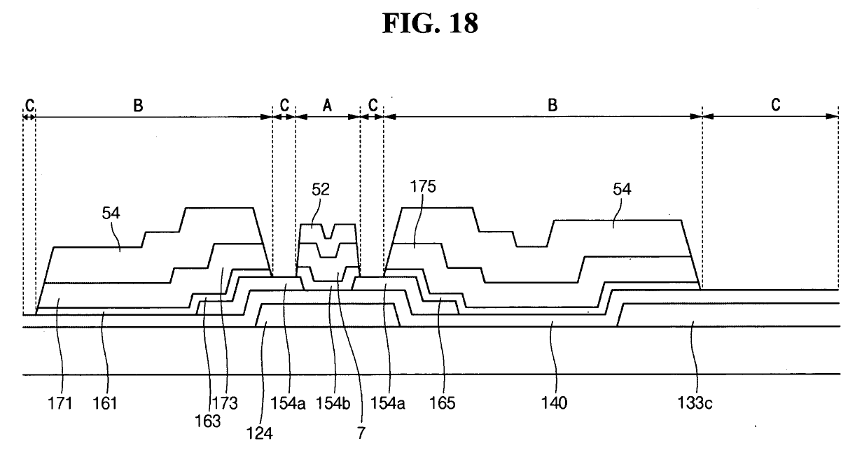

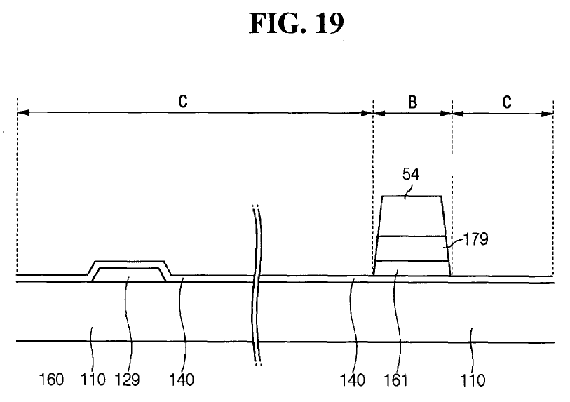

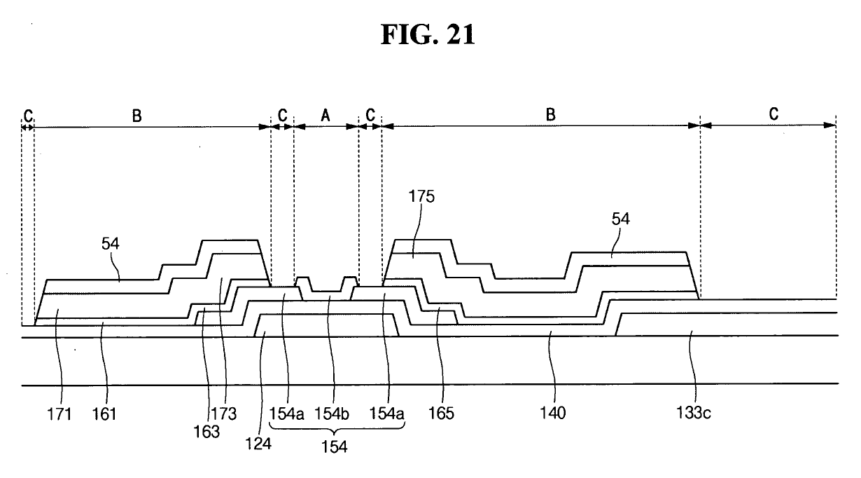

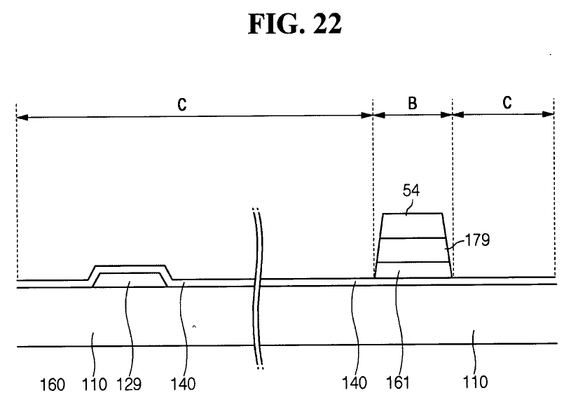

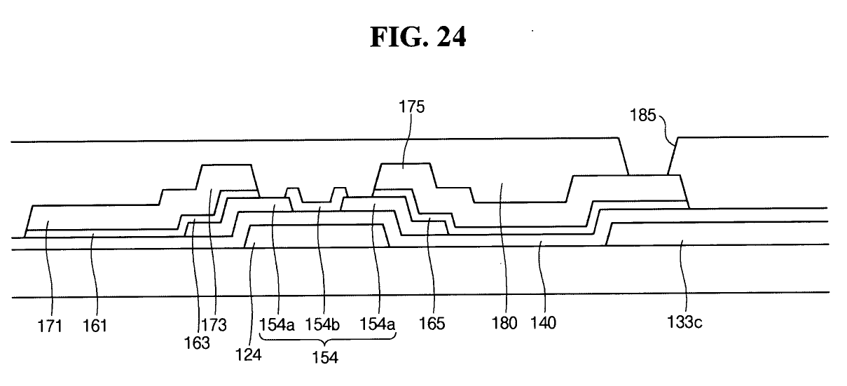

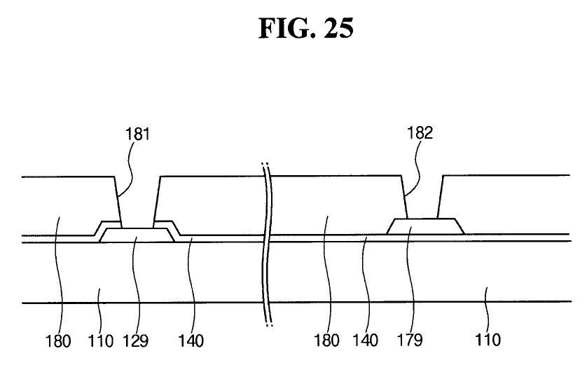

Next, an exemplary embodiment of a method for manufacturing the TFT panel of FIGS. 1 to 5 is described in detail with reference to FIGS. 6 to 25.

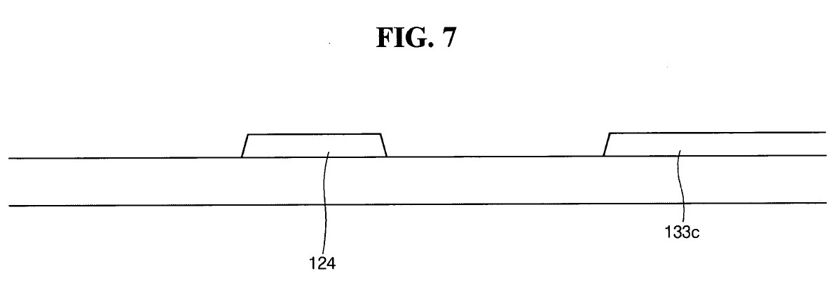

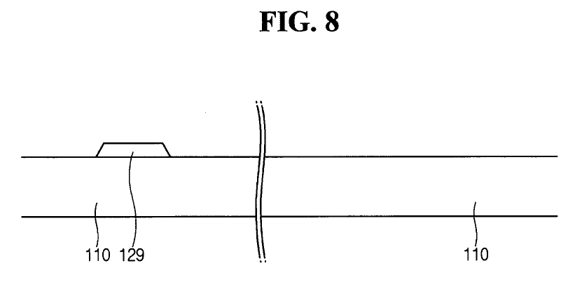

FIG. 6 is a partial plan view of an exemplary TFT panel, showing an intermediate process of the exemplary TFT panel manufacturing method, and FIGS. 7 and 8 are partial cross sectional views of the exemplary TFT panel of FIG. 6, as respectively seen along the section lines VII-VII and VIII-VIII taken therein. First, as illustrated in FIGS. 6 to 8, a plurality of the gate lines 121, including the gate electrodes 124 and end portions 129, and a plurality of the storage electrode lines 131, including the storage electrodes 133a, 133b, and 133c, are formed by depositing conductive layers on the insulating substrate 110 and then performing a photolithography process thereon.

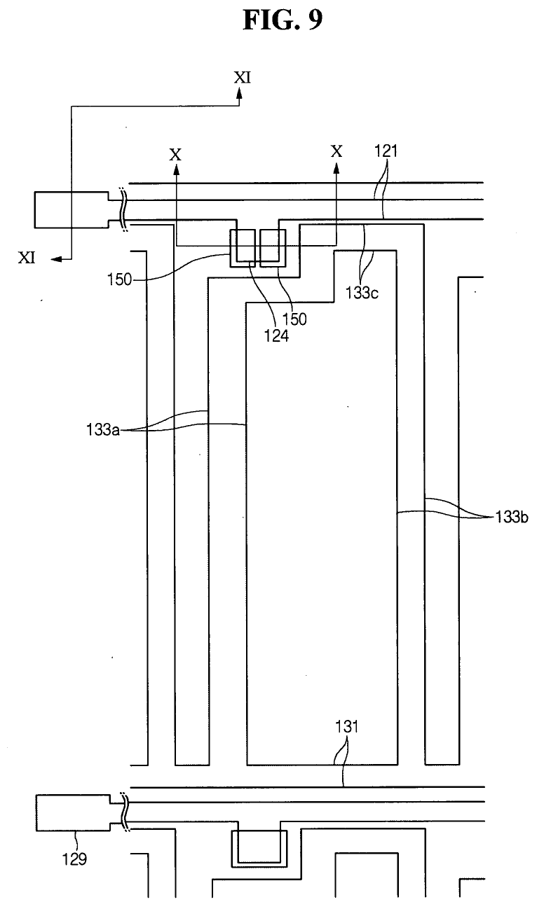

Next, as illustrated n FIGS. 9 to 11, the gate insulating layer 140, made of a silicon nitride, and a first amorphous silicon layer, made of an amorphous silicon, are sequentially formed by performing a plasma enhanced chemical vapor deposition (PECVD) process on the gate lines 121 and the storage electrode lines 131. The first amorphous silicon layer is then patterned to form a silicon pattern 150 thereon.

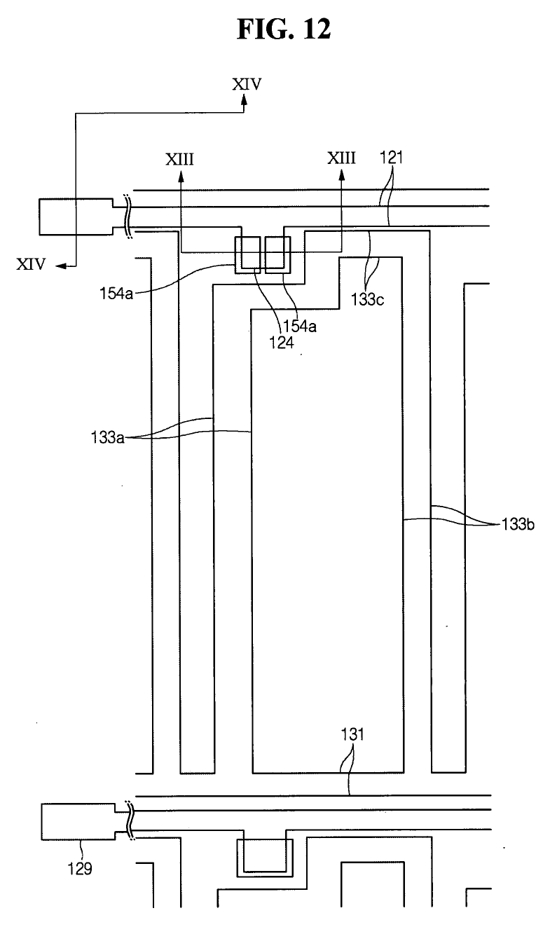

As illustrated in FIGS. 12 to 14, amorphous silicon doped with impurities is then deposited on the semiconductor 150 to form a second amorphous silicon layer. The silicon pattern 150 and the second amorphous silicon layer are then crystallized by performing a solid phase crystallization (SPC) process to form first polycrystalline semiconductors 154a and a polycrystalline silicon layer 160.

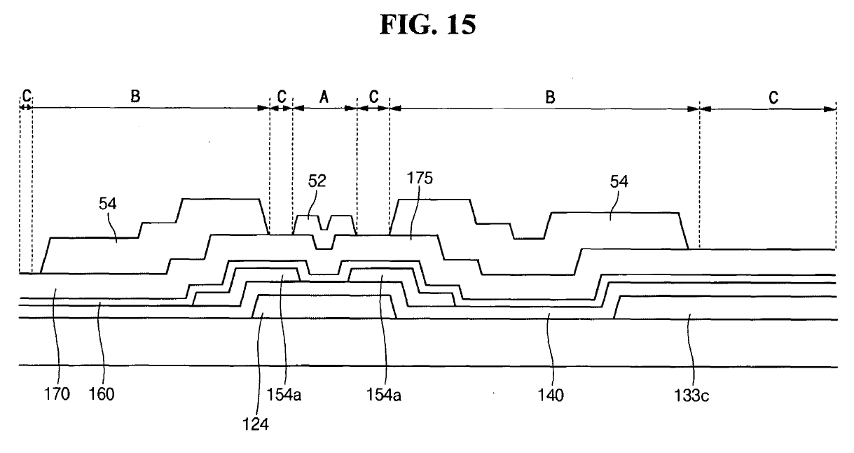

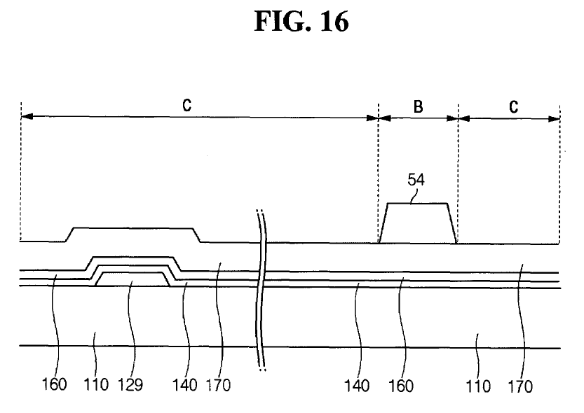

Next, as illustrated in FIGS. 15 and 16, a metal is deposited on the polycrystalline silicon layer 160 to form the data metal layer 170. Photosensitive films 52 and 54 having different thicknesses are then formed on the data metal layer 170. Among the photoresist films 52 and 54, the photoresist film 52 corresponding to a first section (A) overlapping the channel is made thinner than the photoresist film 54 corresponding to a second section (B). As will be understood, the data line 171 and the drain electrode 175 are to be formed in the second section (B). The photoresist film is omitted from a third section (C) that corresponds to the region exclusive of the first and second sections (A) and (B).

One example of a method for forming the photoresist films to incorporate different thicknesses includes providing an exposure mask having areas that are respectively transparent, semi-transparent and opaque. The semi-transparent areas of the mask can comprise a slit pattern, a lattice pattern, or a thin film having a light transmittance that is selected to be intermediate between fully transparent and completely opaque. In masks in which a slit pattern is used, it is preferable that the width of each of the slits or the spacing between them is smaller than the resolution of the exposing apparatus used for the process. In another example, a reflowable photoresist film is used. In particular, by using a typical mask having only transparent and opaque areas, the reflowable photoresist film is first formed, and then a reflow process is performed that enables the photoresist material to flow into a region in the photoresist film was not previously formed, so that a relatively thin photoresist film is formed in that region.

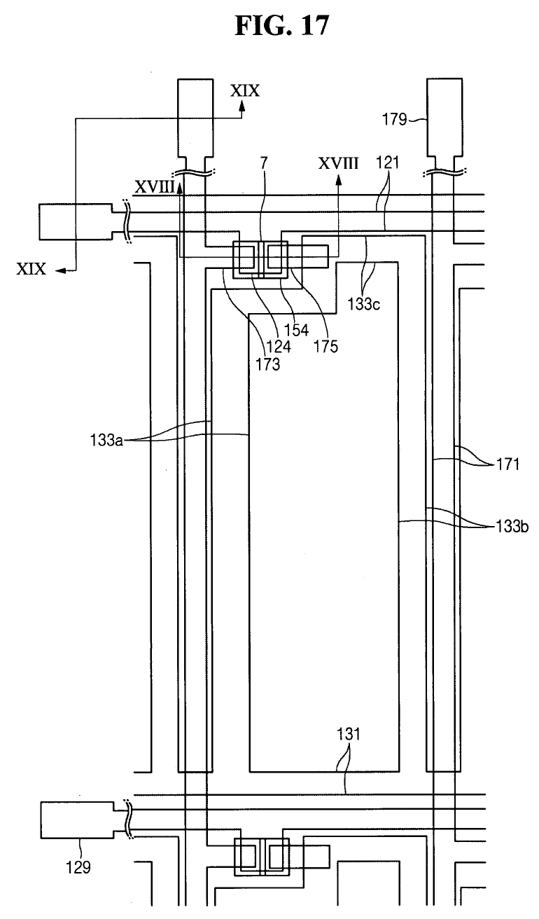

Next, and referring to FIGS. 17 to 19, by using the photoresist film as a mask, the data metal layer is patterned to form the data line 171, the drain electrode 175, and a metal pattern 7, and the polycrystalline silicon layer 160 is sequentially patterned to form the ohmic contacts 161 and 165 and the second polycrystalline semiconductor 154b.

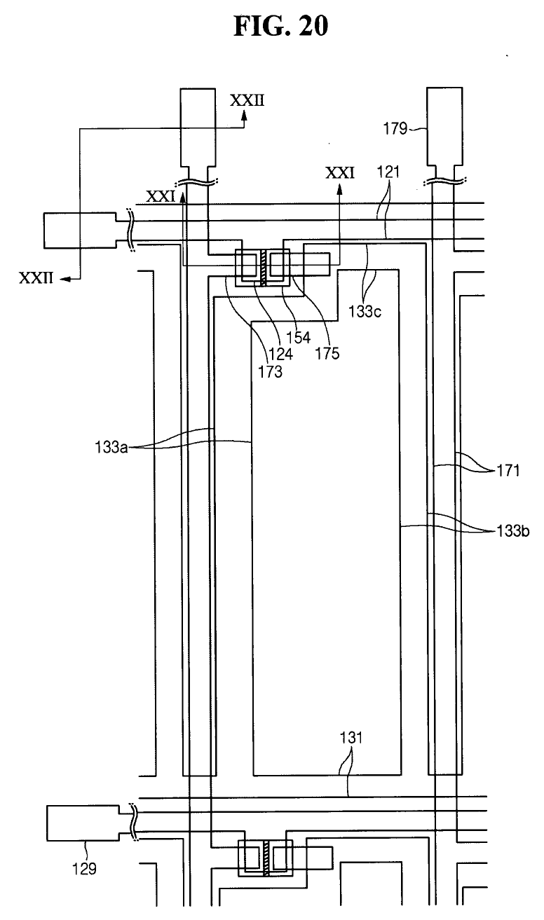

Then, as illustrated in FIGS. 20 to 22, after the photoresist film 52 corresponding to the first section (A) is removed, the metal pattern 7 remaining in the first section is also removed. Also, while the photoresist film 52 corresponding to the first section (A) is being removed, the photoresist layer 54 corresponding to the second section (B) is made thinner.

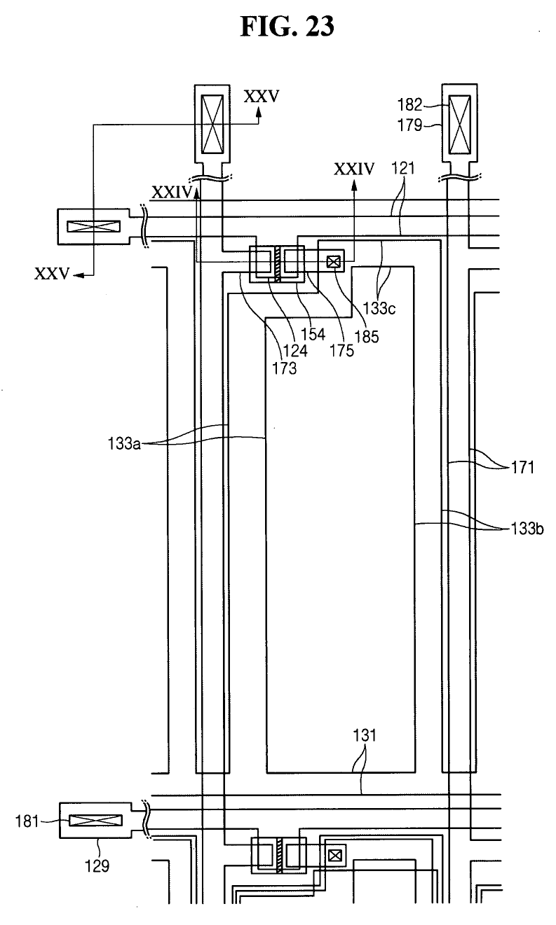

Next, as illustrated in FIGS. 23 to 25, the photoresist pattern corresponding to the second section (B) is removed. Thereafter, a plurality of the contact holes 181, 182, and 185 are formed by depositing the passivation layer 180 on the data lines 171 and the drain electrodes 175 and then performing a photolithography process thereon.

Lastly, as illustrated in FIGS. 1 to 5, the pixel electrode 191 and the contact assistants 81 and 82 are formed by depositing a transparent conductive material, such as ITO and IZO, and then performing a photolithography process thereon.

As described above, since the exemplary TFT panel includes the polycrystalline semiconductor, a high field effect mobility is provided. Additionally, since the TFT employs a bottom gate structure, the TFT can be formed without the use of additional masks and ion doping processes. Therefore, both the number of manufacturing processes and the associated manufacturing costs of the TFT are substantially reduced.

Additionally, the ohmic contacts 163 and 165 have a polycrystalline structure. As described above, since the ohmic contacts 163 and 165 that are disposed between the polycrystalline semiconductors 151 and 154, the source electrode 173, and the drain electrode 175 also have the polycrystalline structure, the advantages of polycrystalline semiconductors can be maximized so as to increase the field effect mobility.

Further, by making the semiconductor 154 of a first polycrystalline semiconductor 154a that is not doped with impurities and a second polycrystalline semiconductor 154b that is doped with impurities, this enables the kink effect to be substantially limited and the leakage current to be substantially reduced.

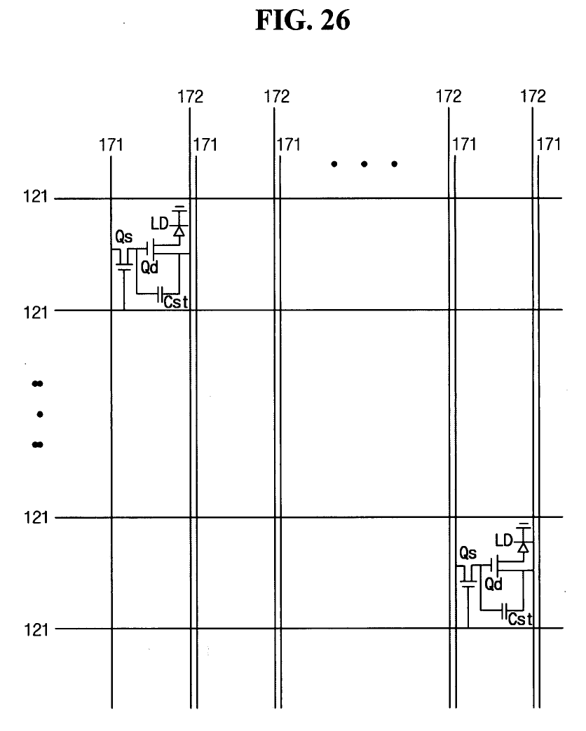

Next, an exemplary embodiment of an organic light emitting diode (OLED) display in accordance with the present invention is described in detail with reference to FIG. 26, which is a partial equivalent circuit diagram thereof.

Referring to FIG. 26, the exemplary OLED display includes a plurality of pixels PX that are connected to a plurality of signal lines 121, 171, and 172 and are arrayed in a substantially rectangular matrix. The signal lines include a plurality of gate lines 121 for transmitting gate (or “scan”) signals, a plurality of data lines 171 for transmitting data signals, and a plurality of driving voltage lines 172 for transmitting driving voltages. The gate lines 121 extend substantially in the row direction, i.e., horizontally in the figure, and are substantially parallel to each other, and the data lines 171 and driving voltage lines 172 extend substantially in the column direction and are substantially parallel to each other and orthogonal to the gate lines.

Each of the pixels includes a switching transistor Qs, a driving transistor Qd, a storage capacitor Cst, and the organic light emitting diode (OLED) LD.

Each switching transistor Qs includes a control terminal, an input terminal, and an output terminal. The control terminal is connected to an associated gate line 121, the input terminal is connected to an associated data line 171, and the output terminal is connected to an associated driving transistor Qd. The switching transistor Qs transmits the data signal applied by the associated data line 171 to the associated driving transistor Qd in response to the scan signal applied to the associated gate line 121.

The driving transistor Qd also includes a control terminal, an input terminal, and an output terminal. The control terminal is connected to the associated switching transistor Qs, the input terminal is connected to the associated driving voltage line 172, and the output terminal is connected to the associated OLED LD. The driving transistor Qd outputs a current ILD, the level of which changes in accordance with a voltage applied between the control and the output terminals thereof.

The capacitor Cst is connected between the control terminal and the input terminal of the driving transistor Qd. The capacitor Cst is charged with the data signal applied to the control terminal of the driving transistor Qd and acts to sustain the signal even when the switching transistor Qs has been turned off.

The OLED LD includes an anode connected to the output terminal of the driving transistor Qd and a cathode connected to a common voltage Vss. The OLED LD emits light with different intensities in accordance with the amount of output current ILD of the driving transistor Qd, so that an image is displayed.

The switching transistor Qs and the driving transistor Qd may be n-channel field effect transistors (FETs). Alternatively, at least one of the switching transistors Qs and the driving transistors Qd may be a p-channel field effect transistor. It should be understood that the connections between the transistors Qs and Qd, the capacitor Cst, and the OLED LD may be varied from those of the exemplary embodiment illustrated in the figures.

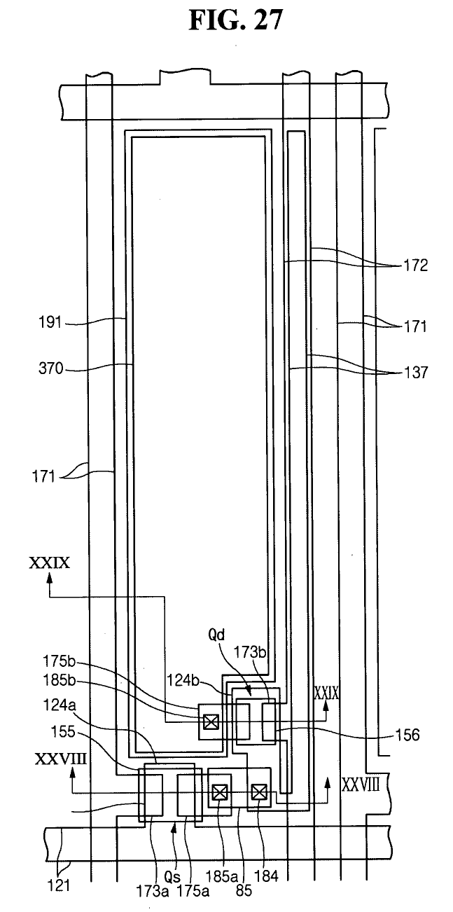

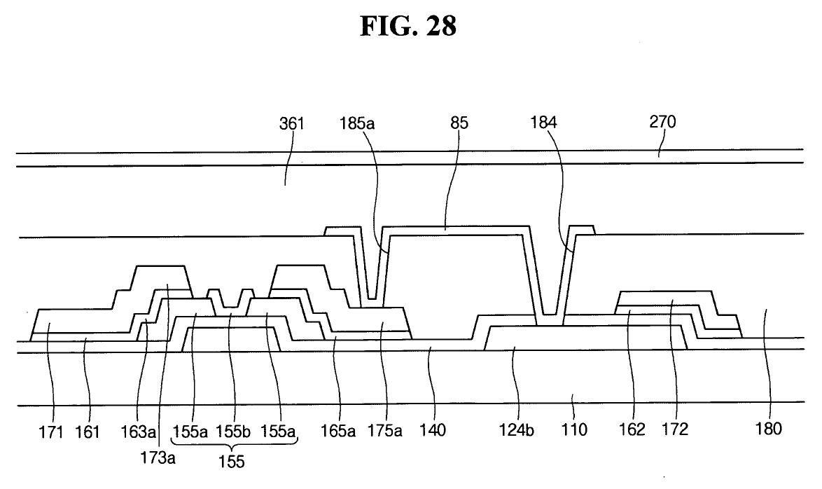

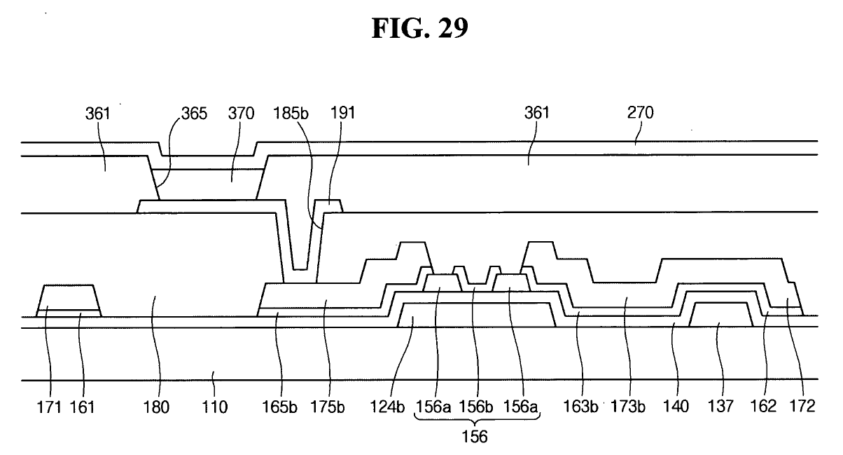

Next, the exemplary OLED display illustrated schematically in FIG. 26 is described in detail in connection with FIGS. 27 to 29, wherein FIG. 27 is a partial plan view of the exemplary OLED display of FIG. 26, showing a single pixel area thereof; and FIGS. 28 and 29 are partial cross sectional views of the exemplary OLED display of FIG. 27, as respectively seen along the section lines XXVIII-XXVIII and XXIX-XXIX taken therein.

A plurality of gate conductors, including a plurality of the gate lines 121 that includes a plurality of first control electrodes 124a and a plurality of second control electrodes 124b, are formed on a insulating substrate 110 made of a transparent glass or a plastic material. Each of the gate lines 121 transmits a respective gate signal and extends generally in a horizontal direction in the figures. Each of the gate lines 121 includes an end portion (not illustrated) having a wide area for connection to other layers or to an external driving circuit (not illustrated). The first control electrode 124a protrudes upwardly from the gate line 121. In an embodiment in which a gate driving circuit (not illustrated) for generating gate signals is integrated on the substrate 110, the gate lines 121 may be extended to directly connect to the gate driving circuit.

The second control electrode 124b is separated from the gate line 121 and includes a storage electrode 137 extending downward, turning to the right, and then extending upward.

The gate conductors 121 and 124b may be made of an aluminum-based metal, a silver-based metal, a copper-based metal, a molybdenum-based metal, chromium (Cr), tantalum (Ta), titanium (Ti) or the like. Additionally, the gate conductors 121 and 124b may have a multi-layered structure, including structures with two conductive layers (not illustrated), each having different physical properties. One of the two conductive layers may be made of a metal having a low resistivity, for example, an aluminum-, a silver- or a copper-based metal, in order to reduce signal delay or voltage drop. In such an embodiment, the other conductive layer is preferably made of a material having good physical, chemical, and/or electrical contact properties with other materials, and in particular, with indium tin oxide (ITO) or indium zinc oxide (IZO). The other layer can comprise, for example, a molybdenum-, chromium-, titanium-, or tantalum-based metal. The combination of a lower chromium-based layer with an upper aluminum-based layer, and the combination of a lower aluminum-based layer with an upper molybdenum-based layer are good examples. However, it should be understood that the gate conductors 121 and 124b may be made of various other metals and conductive materials, as well.

Preferably, the side surfaces of the gate conductors 121 and 124b are slanted with respect to the surface of the insulating substrate 110 upon which they are formed, and the angle of the slant is desirably in a range of from about 30° to about 80°.

A gate insulating layer 140 made of SiNx, SiOx, or the like is formed on the gate conductors 121 and 124b.

A plurality of first and second island-shaped semiconductors 155 and 156 made of polycrystalline silicon are formed on the gate insulating layer 140. The first and second island-shaped semiconductors 155 and 156 include first polycrystalline semiconductors 155a and 156a, which are not doped with impurities, and second polycrystalline semiconductors 155b and 156b, which are doped with impurities, respectively. The second polycrystalline semiconductors 155b and 156b are made of polycrystalline silicon that is heavily doped with n-type impurities, such as phosphorus (P) or the like. The first and second semiconductors 155 and 156 are disposed on the first and second control electrodes 124a and 124b, respectively.

A plurality of line-shaped ohmic contacts 161 and 162 and a plurality of island-shaped ohmic contacts 165a and 165b are formed on the first and second semiconductors 155 and 156. The ohmic contacts 161, 162, 165a, and 165b are made of the same material as the second polycrystalline semiconductors 155b and 156b. The line-shaped ohmic contacts 161 and 162 extend generally in the horizontal direction in the figures, and include a plurality of protrusions 163a and 163b that protrude toward the first and second control electrodes 124a and 124b. A pair of the protrusions 163a, along with the island-shaped ohmic contact 165a and a pair of the protrusion 163b and the island-shaped ohmic contact 165b, are disposed on the first and second semiconductors 155 and 156, respectively.

A plurality of data conductors, including a plurality of data lines 171, a plurality of driving voltage lines 172, and a plurality of first and second output electrodes 175a and 175b, are formed on the ohmic contacts 161, 162, 165a, and 165b.

Each of the data lines 171 transmits a respective data signal and extends in a generally vertical direction in the figures to intersect the gate lines 121 generally orthogonally. Each of the data lines 171 includes a plurality of input electrodes 173a extending toward the first control electrodes 124a and an end portion (not illustrated) having a wide area for connection to other layers or an external driving circuit. In an embodiment in which a data driving circuit (not illustrated) for generating the data signals is integrated on the substrate 110, the data lines 171 may be extended to directly connect to the data driving circuit.

The driving voltage lines 172 that transmit driving voltages also generally extend in a vertical direction so as to intersect the gate lines 121. Each of the driving voltage lines 172 includes a plurality of second input electrodes 173b extending toward the second control electrodes 124b. The driving voltage line 172 overlaps the storage electrode 137 and may be connected thereto.

The first and second output electrodes 175a and 175b are separated from each other and from the data lines 171 and the driving voltage lines 172 as well. The first input electrode 173a and the first output electrode 175a face each other, with the first control electrode 124a interposed therebetween, and the second input electrode 173b and the second output electrode 175b face each other with the second control electrode 124b interposed therebetween.

Preferably, The data conductors 171, 172, 175a, and 175b are made of a refractory metal, such as molybdenum (Mo), chromium (Cr), or tantalum (Ta), and titanium (Ti), or a respective alloy thereof. The data conductors 171, 172, 175a, and 175b may incorporate a multi-layered structure, including a refractory metal layer (not illustrated) and a low-resistivity conductive layer (not illustrated). An example of a two-layered structure may comprise a lower layer comprising chromium or molybdenum and an upper layer comprising aluminum, and an exemplary three-layered structure may comprise a lower comprising molybdenum, an intermediate layer comprising aluminum, and an upper layer comprising molybdenum. However, it should be understood that the data conductors 171, 172, 175a, and 175b may comprise various other metals or conductive materials, as well.

Similar to those of the gate conductors 121 and 124b above, the side surfaces of the data conductors 171, 172, 175a, and 175b may also be slanted with respect to the surface of the insulating substrate 110, and desirably, with a slant angle in a range of from about 30° to about 80°.

The ohmic contacts 161, 162, 165a, and 165b and the data conductors 171, 172, 175a, 175b all incorporate substantially the same planar pattern. The ohmic contacts 163a, 163b, 165a, and 165b are interposed between the first and second output electrodes 175a and 175b, the first and second input electrodes 173a and 173b, and the semiconductor 154, and function to reduce the respective contact resistances therebetween.

The semiconductors 155 and 156 include exposed portions that are uncovered by the data conductors 171, 172, 175a, and 175b, such as the portions disposed between the input electrodes 173a and 173b and the output electrodes 175a and 175b.

A passivation layer 180 is formed on the data conductors 171, 172, 175a, and 175b and the exposed portions of the semiconductors 155 and 156. The passivation layer 180 is made of an inorganic insulating material, such as a silicon nitride or a silicon oxide, an organic insulating material, or a low-dielectric-constant insulating material. Preferably, the organic and low dielectric-constant insulating materials have a dielectric constant of 4.0 or less. Examples of low dielectric-constant insulating materials are a-Si:C:O and a-Si:O:F, which are formed by a plasma enhanced chemical vapor deposition (PECVD). The passivation layer 180 may be made of an organic insulating material having a photosensitivity, and may include a surface that is planarized. Alternatively, the passivation layer 180 may incorporate a two-layered structure comprising a lower inorganic layer and an upper organic layer in order to provide the excellent insulating property of an organic layer and to protect the exposed portions of the semiconductors 155 and 156.

A plurality of contact holes 185a and 185b that expose the first and second output electrodes 175a and 175b, respectively, are formed on the protectively layer 180. A plurality of contact holes 184 that expose the second control electrodes 124b are formed on the gate insulating layer 140.

A plurality of pixel electrodes 191 and a plurality of connecting members 85 are formed on the passivation layer 180. These components may be made of a transparent conductive material, such as indium tin oxide (ITO) and indium zinc oxide (IZO), or the like, or alternatively, of a reflective metal, such as aluminum (Al), silver (Ag), chromium (Cr), or respective alloys thereof.

The pixel electrode 191 is physically and electrically connected to the second output electrode 175b through the contact hole 185b. The connecting member 85 is connected to the second control electrode 124b and the first output electrode 175a through the contact holes 184 and 185a.

Partition walls 361 are formed on the passivation layer 180. The partition walls 361 surround the pixel electrode 191 like a bank to define an opening 365, and are made of an organic insulating material or an inorganic insulating material. In addition, the partition walls 361 may be made of a photoresist material that includes a black pigment. In such an embodiment, the partition walls 361 serve as a light-blocking member and can be formed by a very simple process.

An organic light emitting member 370 is formed in the opening 365 above the pixel electrode 191 defined by the partition walls 361. The organic light emitting member 370 is made of an organic material that emits light corresponding to one of a set of primary colors, such as red, green, and blue. The OLED display displays a desired image by using a spatial combination of the primary colors emitted by the organic light emitting member 370.

The organic light emitting member 370 may have a multi-layered structure, including a light emitting layer and an auxiliary layer (not illustrated) for improving the light emitting efficiency of the light emitting layer. An example of the auxiliary layer may comprise an electron transport layer (ETL) (not illustrated) and a hole transport layer (HTL) (not illustrated) that balance electrons and holes, and an electron injecting layer (EIL) (not illustrated) and an hole injecting layer (HIL) (not illustrated) that function to enhance injection of the electrons and the holes.

A common electrode 270 is formed on the organic light emitting member 370. The common electrode 270 has a common voltage Vss applied to it and is made of a reflective metal, such as calcium (Ca), barium (Ba), magnesium (Mg), aluminum (Al), or silver (Ag), and a transparent conductive material, such as indium tin oxide (ITO) and indium zinc oxide (IZO).

In the OLED display, the first control electrode 124a connected to the gate line 121, the first input electrode 173a connected to the data line 171, and the first output electrode 175a, together with the first semiconductor 155, constitute the switching TFT Qs, with the channel of the switching TFT Qs being formed in the first semiconductor 155 between the first input electrode 173a and the first output electrode 175a. In addition, the second control electrodes 124b connected to the first output electrode 175a, the second input electrode 173b connected to the driving voltage line 172, and the second output electrode 175b connected to the pixel electrode 191, together with the second semiconductor 156, constitute the driving TFT Qd, with the channel of the driving TFT Qd being formed in the second semiconductor 156 between the second input electrode 173b and the second output electrode 175b. The pixel electrode 191, the organic light emitting member 370, and the common electrode 270 constitute the OLED LD. The pixel electrode 191 and the common electrode 270 serve as the anode and the cathode, respectively. Alternatively, the pixel electrode 191 and the common electrode 270 may serve as the cathode and the anode, respectively. The storage electrodes 137 and the driving voltage lines 172 overlapping each other constitute the storage capacitors Cst.

The OLED display displays an image by emitting light in the downward or upward direction with respect to the insulating substrate 110. In a top emission type of OLED display, in which the image is displayed in the upward direction with respect to the insulating substrate 110, an opaque pixel electrode 191 and a transparent common electrode 270 are employed, whereas, in a bottom emission type OLED display, in which the image is displayed in the downward direction with respect to the insulating substrate 110, a transparent pixel electrode 191 and an opaque common electrode 270 are employed.

In accordance with the exemplary embodiments above, polycrystalline semiconductors are employed, and accordingly, a high field effect mobility is obtained. In addition, a bottom gate structure is employed. As a result, the TFTs can be formed without the use of additional masks and ion doping processes, thereby enabling manufacturing processes and costs to be substantially reduced.

Additionally, because the semiconductors comprise a semiconductor material that is doped with impurities, together with a semiconductor material that is not doped with impurities, the kink effect can be controlled as above and leakage current substantially reduced.

By now, those of skill in this art will appreciate that many modifications, substitutions and variations can be made in and to the TFTs, display panels incorporating them, and the methods for making them of the present invention without departing from its spirit and scope. In light of this, the scope of the present invention should not be limited to that of the particular embodiments illustrated and described herein, as they are only exemplary in nature, but instead, should be fully commensurate with that of the claims appended hereafter and their functional equivalents.

What is claimed is:

1. A TFT, comprising:
a substrate;
a gate electrode formed on the substrate;
a gate insulating layer formed on the gate electrode;
a polycrystalline semiconductor formed on the gate insulating layer and overlapping the gate electrode;
a source electrode partially overlapping the polycrystalline semiconductor; and,
a drain electrode partially overlapping the polycrystalline semiconductor,
wherein the polycrystalline semiconductor comprises at least one first polycrystalline semiconductor that is doped with impurities and at least two second polycrystalline semiconductors that are not doped with impurities, and
wherein the first polycrystalline semiconductor is disposed between ones of the second semiconductors.

2. The TFT of claim 1, further comprising ohmic contacts respectively disposed between the source electrode and the second polycrystalline semiconductor, and between the drain electrode and the second polycrystalline semiconductor.

3. The TFT of claim 2, wherein the ohmic contacts incorporate substantially the same patterns as those of the source electrode and the drain electrode.

4. The TFT of claim 2, wherein the ohmic contacts and the first polycrystalline semiconductor are made of the same material.

5. The TFT of claim 1, wherein the source electrode and the drain electrode overlap the second polycrystalline semiconductor.

6. The TFT of claim 1, wherein the impurities are n-type.

7. A display panel, comprising:
a first substrate;
a gate line formed on the first substrate;
a polycrystalline semiconductor formed on the gate line;
a data line formed on the polycrystalline semiconductor and comprising a first electrode;
a second electrode formed on the polycrystalline semiconductor and facing the first electrode; and,
a pixel electrode connected to the second electrode,
wherein the polycrystalline semiconductor comprises at least one first polycrystalline semiconductor that is doped with impurities and at least two second polycrystalline semiconductors that are not doped with impurities, and
wherein the first polycrystalline semiconductor is disposed between ones of the second polycrystalline semiconductors.

8. The display panel of claim 7, further comprising ohmic contacts respectively formed between the first electrode and the second polycrystalline semiconductor, and between the second electrode and the second polycrystalline semiconductor.

9. The display panel of claim 8, wherein the ohmic contacts have substantially the same patterns as those of the first electrode and the second electrode.

10. The display panel of claim 8, wherein the ohmic contacts and the first polycrystalline semiconductor are made of the same material.

11. The display panel of claim 7, wherein the first electrode and the second electrode overlap the second polycrystalline semiconductor.

12. A method of manufacturing a TFT, the method comprising:
forming a gate electrode on a substrate;
forming a first amorphous silicon layer on the gate electrode;
forming a silicon pattern by patterning the first amorphous silicon layer;
forming a second amorphous silicon layer that is doped with impurities on the silicon pattern;
forming a first polycrystalline semiconductor and a polycrystalline silicon layer by crystallizing the silicon pattern and the second amorphous silicon layer;
forming a metal layer on the polycrystalline, silicon layer; and
forming a metal pattern, a second polycrystalline semiconductor, and ohmic contacts by patterning the metal layer and the polycrystalline silicon layer.

13. The method of claim 12, wherein the silicon pattern and the second amorphous silicon layer is crystallized by a solid phase crystallization (SPC) process.

14. The method of claim 12, wherein the formation of the metal pattern, the second polycrystalline semiconductor, and the ohmic contacts further comprises:
forming first and second photoresist layers on the metal layer, the second layer being thicker than the first layer;
forming the metal pattern, the second polycrystalline semiconductor, and ohmic contacts by patterning the metal layer and the polycrystalline silicon layer using the first and second photoresist layers as masks;
removing the first photoresist layer on the metal pattern;
etching to remove the metal pattern using the second photoresist layer as a mask; and,
removing the second photoresist layer.

15. A method of manufacturing a display panel, the method comprising:
forming a gate line on a substrate;
forming a first amorphous silicon layer on the gate line;
forming a silicon pattern by patterning the first amorphous silicon layer;
forming a second amorphous silicon layer that is doped with impurities on the silicon pattern;
forming a first polycrystalline semiconductor and a polycrystalline silicon layer by crystallizing the silicon pattern and the second amorphous silicon layer;
forming a metal layer on the polycrystalline silicon layer;
forming a data line, a drain electrode, a metal pattern, a second polycrystalline semiconductor, and ohmic contacts by patterning the metal layer and the polycrystalline silicon layer;
forming a passivation layer, including contact holes exposing the drain electrode on the data line, the drain electrode, the first polycrystalline semiconductor, and the second polycrystalline semiconductor; and,
forming a pixel electrode connected to the drain electrode through the contact holes on the passivation layer.

16. The method of claim 15, wherein the silicon pattern and the second amorphous silicon layer is crystallized by a solid phase crystallization (SPC) process.

17. The method of claim 15, wherein the formation of the metal pattern, the second polycrystalline semiconductor, and the ohmic contacts further comprises:
forming first and second photoresist layers on the metal layer, the second layer being thicker than the first layer;
forming the metal pattern, the second polycrystalline semiconductor, and ohmic contacts by patterning the metal layer and the polycrystalline silicon layer using the first and second photoresist layers as masks;
removing the first photoresist layer on the metal pattern;
etching to remove the metal pattern using the second photoresist layer as a mask; and,
removing the second photoresist layer.
